(19) United States
(12) Patent Application Publication
(10) Pub. No.: US 2025/0125234 A1
(43) Pub. Date: Apr. 17, 2025

(54) INTERPOSER CONNECTION STRUCTURES BASED ON WIRE BONDING

(71) Applicant: QUALCOMM Incorporated, San Diego, CA (US)

(72) Inventors: Manuel ALDRETE, Encinitas, CA (US); Rajneesh KUMAR, San Diego, CA (US); Zhijie WANG, San Diego, CA (US); Aniket PATIL, San Diego, CA (US); Srikanth KULKARNI, Pleasanton, CA (US)

(21) Appl. No.: 18/486,970

(22) Filed: Oct. 13, 2023

(51) Int. Cl. H01L 23/498; H01L 21/48; H01L 21/56; H01L 23/00; H01L 25/10

(52) U.S. Cl. CPC H01L 23/49811; H01L 21/4857; H01L 21/4885; H01L 21/565; H01L 23/49822; H01L 23/49838; H01L 23/49866; H01L 24/16; H01L 24/32; H01L 24/73; H01L 25/105; H01L 2224/16227; H01L 2224/32225; H01L 2224/73253; H01L 2225/1023; H01L 2225/1058; H01L 2924/182

(57) ABSTRACT

In an aspect, an integrated circuit (IC) package includes a base structure, an IC component disposed on the base structure, a plurality of interposer connection structures disposed on the base structure, and an interposer structure disposed over the IC component and the plurality of interposer connection structures. The plurality of interposer connection structures is configured to connect the base structure and the interposer structure. Each interposer connection structure of the plurality of interposer connection structures includes a bond ball portion that is connected to the base structure, and a bond wire portion that is coupled to the bond ball portion and extends toward the interposer structure. A width of the bond ball portion is greater than a width of the bond wire portion.

### TECHNICAL FIELD

The present disclosure generally relates to an integrated circuit (IC) package, and more particularly, to an IC package that includes interposer connection structures formed based on a wire bonding process.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

For example, a package on a package (PoP) packaging method may correspond to vertically combining discrete logic and/or memory chips or dies to reduce the IC device size. In some examples, the PoP packaging method may be used in conjunction with a molded embedded package packaging method, which may be referred to as a molded embedded package on a package packaging method or a MEP packaging method. In some examples, in an IC package formed based on the PoP packaging method and/or the MEP packaging method, each chip may be mounted on a respective substrate, and an interposer may be used for coupling different substrates with chips mounted thereon.

In some examples, an interposer may be disposed over a package substrate, where the package substrate may have an IC component mounted thereon. The interposer and the package substrate may be connected through a plurality of interposer connection structures. A horizontal size of the IC package may be determined based on a pitch of the plurality of interposer connection structures and a count of the plurality of interposer connection structures. Also, a thickness of the IC component that can be placed between the interposer and the package substrate may be limited by a height of the plurality of interposer connection structures. In some examples, there may be a challenge to configure the interposer connection structures to have a reduced pitch for reducing the horizontal size of an IC package and to have an increased height for accommodating an IC component with a substantial thickness.

Accordingly, there is a need for improved interposer connection structures for an IC package and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an integrated circuit (IC) package includes a base structure; an IC component disposed on the base structure; a plurality of interposer connection structures disposed on the base structure; and an interposer structure disposed over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

In an aspect, a method of manufacturing an integrated circuit (IC) package includes disposing an IC component on a base structure; disposing a plurality of interposer connection structures on the base structure; and disposing an interposer structure over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

In an aspect, an electronic device includes an integrated circuit (IC) package that comprises: a base structure; an IC component disposed on the base structure; a plurality of interposer connection structures disposed on the base structure; and an interposer structure disposed over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a cross-sectional view of an integrated circuit (IC) package, according to aspects of the disclosure.

FIGS. 2A-2D illustrate portions of IC package examples, according to aspects of the disclosure.

FIGS. 3A-3F illustrate structures at various stages of manufacturing an IC package, according to aspects of the disclosure.

FIGS. 4A-4H illustrate structures at various stages of manufacturing an IC package, according to aspects of the disclosure.

FIGS. 5A-5F illustrate structures at various stages of manufacturing an IC package, according to aspects of the disclosure.

FIGS. 6A-6D illustrate structures at various stages of manufacturing an IC package, according to aspects of the disclosure.

FIG. 7 illustrates a method for manufacturing an IC package, according to aspects of the disclosure.

FIG. 8 illustrates a mobile device, according to aspects of the disclosure.

FIG. 9 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to an integrated circuit (IC) package that includes interposer connections structures formed based on a wire bonding process. In some aspects, the interposer connections structures formed based on a wire bonding process may have a reduced pitch for reducing a horizonal size of the IC package and/or increasing a count per unit area of the interposer connections structures. In some aspects, the interposer connections structures formed based on a wire bonding process may have a height-to-pitch ratio greater than those of other solutions (e.g., copper core balls or plated copper pillars) for accommodating a thickener IC component between an interposer structure and a base structure of the IC package. Also, the manufacturing cost of the interposer connection structures based on the wire bonding process may be less expensive than other alternative implementations based on copper core balls or plated copper pillars.

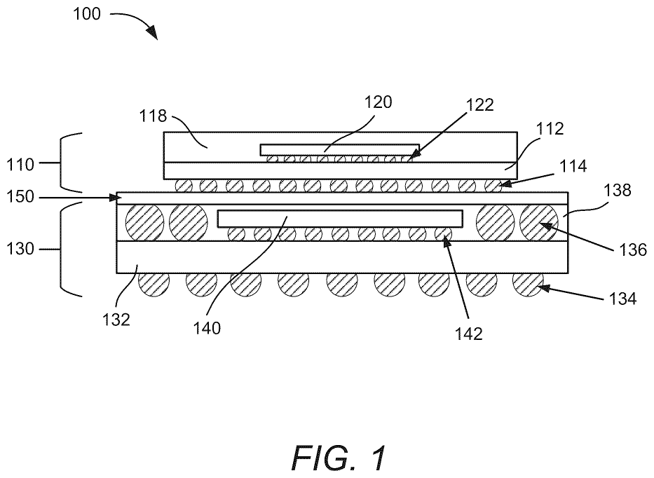

FIG. 1 is a cross-sectional view of an IC package 100, according to aspects of the disclosure. In some aspects, FIG. 1 is a simplified cross-sectional view of the IC package 100, and certain details and components of the IC package 100 may be simplified or omitted in FIG. 1.

In some aspects, as shown in FIG. 1, the IC package 100 may be based on the PoP packaging method. The IC package 100 may include a first packaging portion 110 over a second packaging portion 130, with an interposer structure 150 coupling the first packaging portion 110 to the second packaging portion 130.

The first packaging portion 110 may include a first base structure 112 (e.g., a package substrate) and first packaging terminals 114 (e.g., solder bumps or copper pillar bumps) electrically coupling the first base structure 112 and the interposer structure 150. In some aspects, the first packaging terminals 114 may also be configured to mechanically coupling the first base structure 112 and the interposer structure 150. The first packaging portion 110 may include a first IC chip 120 mounted on the first base structure 112 through first IC terminals 122 (e.g., solder bumps or copper pillar bumps). In some aspects, the first packaging portion 110 may further include a first molding compound portion 118 disposed on the first base structure 112 and covering the first IC chip 120. In some aspects, the first molding compound portion 118 may only surround the first IC terminals 122 without covering the first IC chip 120. In some aspects, the first packaging portion 110 may not include the first molding compound portion 118. In some aspects, the first IC terminals 122, the first molding compound portion 118, or both may also be configured to mechanically coupling the first IC chip 120 and the first base structure 112.

The second packaging portion 130 may include a second base structure 132 (e.g., a package substrate) and second packaging terminals 134 (e.g., solder bumps or copper pillar bumps) for electrically coupling the IC package 100 to an external component, such as a circuit board. The second packaging portion 130 may include a second IC chip 140 mounted on the second base structure 132 through second IC terminals 142 (e.g., solder bumps or copper pillar bumps). The second packaging portion 130 may include interposer connection structures 136 electrically coupling the second base structure 132 and the interposer structure 150.

In some aspects, the second packaging portion 130 may further include a second molding compound portion 138 disposed on the second base structure 132 and covering the second IC chip 140. In some aspects, the second molding compound portion 138 may surround the interposer connection structures 136. In some aspects, the second molding compound portion 138 may only surround the second IC terminals 142 without covering the second IC chip 140 and/or without surrounding the interposer connection structures 136. In some aspects, the second packaging portion 130 may not include the second molding compound portion 138.

In some aspects, the second IC terminals 142, the second molding compound portion 138, or both may also be configured to mechanically coupling the second IC chip 140 and the second base structure 132. In some aspects, the interposer connection structures 136, the second molding compound portion 138, or both may also be configured to mechanically coupling the second base structure 132 and the interposer structure 150.

As used herein, the interposer structure 150 is configured to electrically couple the base structures 112 and 132 and in some aspects coupling the IC chips 120 and 140 through the base structures 112 and 132 and optionally additional components (e.g., other IC chips, active components such as discrete transistors or Op Amps, and/or passive components such as resistors, capacitors, and/or inductors) formed on or embedded in the base structures 112 and/or the base structures 132.

In some aspects, the interposer connection structures 136 may include copper core balls or plated copper pillars. However, these implementation examples of the interposer connection structures 136 may not be suitable for meeting both the pitch and the height requirements for some applications.

It will be appreciated that the illustrated configuration and descriptions provided herein are merely to aid in the explanation of the various aspects disclosed herein. Accordingly, the forgoing illustrative examples should not be construed to limit the various aspects disclosed and claimed herein.

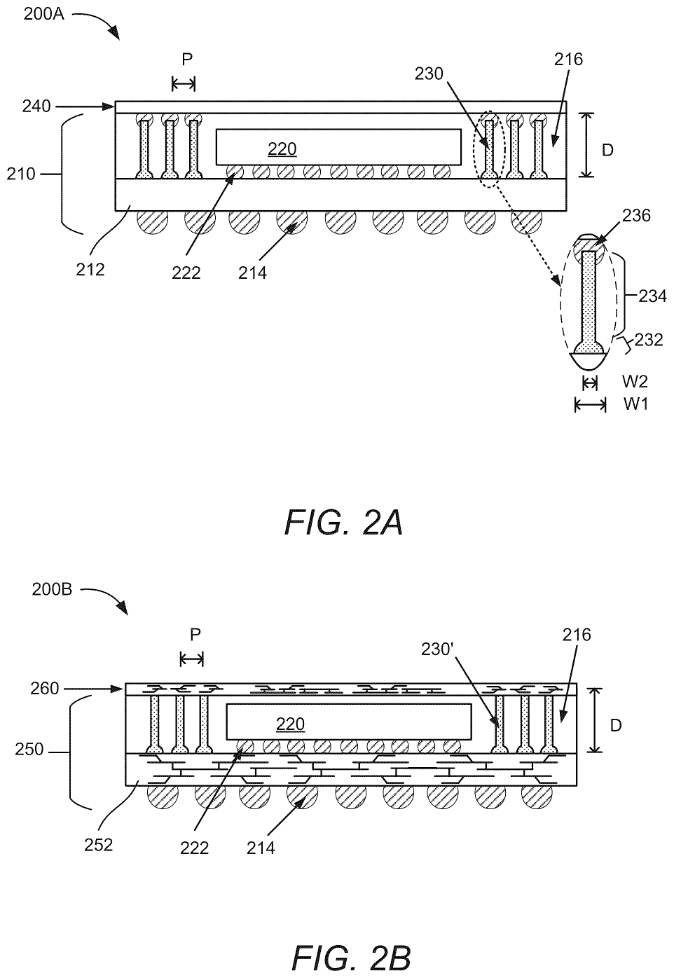

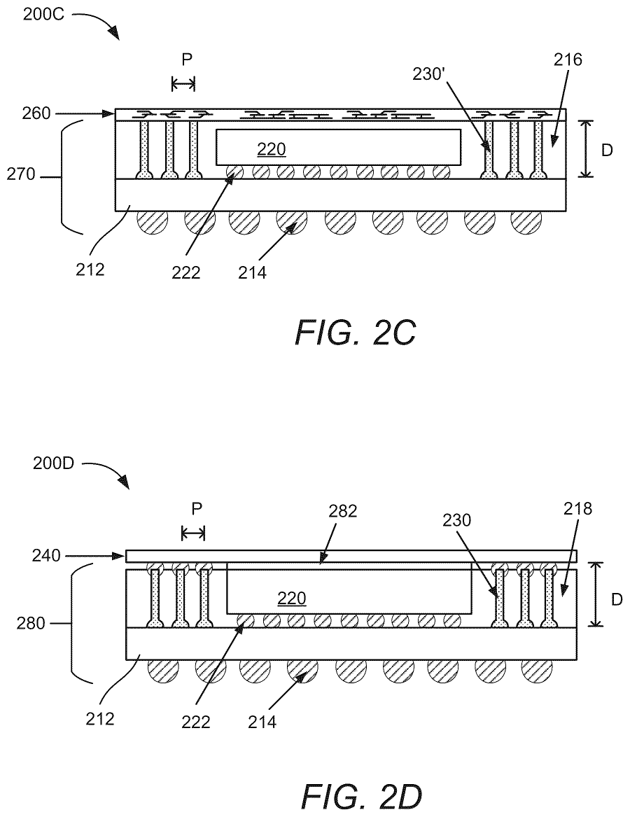

FIG. 2A illustrates a portion of a first IC package example 200A, according to aspects of the disclosure. As shown in FIG. 2A, the first IC package example 200A may include a packaging portion 210 and an interposer structure 240. In some aspects, the packaging portion 210 may correspond to the second packaging portion 130 in FIG. 1, and the interposer structure 240 may correspond to the interposer structure 150 in FIG. 1. In some aspects, certain details and components of the first IC package example 200A may be simplified or omitted in FIG. 2A.

As shown in FIG. 2A, the packaging portion 210 may include a base structure 212 and an IC component 220 disposed on the base structure 212. The IC component 220 may be mounted on the base structure 212 through IC terminals 222 (e.g., solder bumps or copper pillar bumps). Also, the first IC package example 200A may include packaging terminals 214 (e.g., a plurality of solder bumps or copper pillar bumps) under the base structure 212 and configured for connecting the IC package 200A to an external component (e.g., a circuit board). In some aspects, the base structure 212 may be a package substrate with conductive structures formed therein. In some aspects, a package substrate may be formed by attaching one or more patterned conductive layers on a substrate core that may include resin and reinforced components (e.g., glass fibers) embedded therein. In some aspects, a package substrate may have a coreless configuration.

In some aspects, the IC component 220 may be an IC chip or may be an assembly having a package substrate of its own and an IC chip mounted on the package substrate of the assembly. Moreover, the interposer structure 240 may be disposed over the IC component 220 and the base structure 212. In some aspects, the interposer structure may include a package with conductive structures formed therein.

The first IC package example 200A further includes a plurality of interposer connection structures 230 disposed on the base structure 212. In some aspects, the plurality of interposer connection structures 230 may be configured to connect the base structure 212 and the interposer structure 240. In some aspects, as shown in the enlarged view of an example interposer connection structure 230, each interposer connection structure of the plurality of interposer connection structures 230 may include a bond ball portion 232 that is connected to the base structure 212, and a bond wire portion 234 that is coupled to the bond ball portion 232 and extends toward the interposer structure 240. In some aspects, an lower end of each interposer connection structure may be connected to a corresponding conductive pad of the base structure 212, and an upper end of each interposer connection structure may be connected to a corresponding conductive pad of the interposer structure 240. In some aspects, each interposer connection structure of the plurality of interposer connection structures 230 may further include a solder portion 236 connecting the upper end of the corresponding bond wire portion 234 and the interposer structure 240.

In some aspects, the interposer connection structures 230 are formed based on a wire bonding process. In some aspects, a width W1 of the bond ball portion 232 maybe greater than a width W2 of the bond wire portion 234. In some aspects, the bond ball portion 232 and the bond wire portion 234 of each one of the plurality of interposer connection structures 230 may form a bond wire pillar and may include a metal. In some aspects, the metal comprises copper, aluminum, gold, or a combination thereof.

In some aspects, the first IC package example 200A may further include a molding compound portion 216 between the base structure 212 and the interposer structure 240 and surrounding at least the bond ball portions 232 and a portion of the bond wire portions 234 of the plurality of interposer connection structures 230. In some aspects, the molding compound portion 216 may be in contact with an upper surface of the base structure 212 and a lower surface of the interposer structure 240.

In some aspects, the plurality of interposer connection structures 230 may have a pitch P equal to or less than 150 micrometers (μm). In some aspects, the plurality of interposer connection structures 230 may have the pitch P ranging from 100 to 150 μm. In some aspects, a distance D between the upper surface of the base structure 212 and the lower surface of the interposer structure 240 may be greater than 200 μm.

In some aspects, compared with the IC package 100, the plurality of interposer connection structures 230 in the first IC package example 200A may be made based on a wire bonding process, which may have a tighter pitch and have a greater distance between the base structure 212 and the interposer structure 240 than other alternative implementations based on copper core balls or plated copper pillars. Therefore, the plurality of interposer connection structures 230 based on a wire bonding process may help to reduce the package size (e.g., horizontal size) and/or increase the count of the interposer connection structures. With the plurality of interposer connection structures 230 based on a wire bonding process, a thicker IC component may be put in an IC package with a low interposer connection pitch. Moreover, the manufacturing cost of the interposer connection structures 230 based on a wire bonding process may be less expensive than other alternative implementations based on copper core balls or plated copper pillars.

FIG. 2B illustrates a portion of a second IC package example 200B, according to aspects of the disclosure. As shown in FIG. 2B, the second IC package example 200B may include a packaging portion 250 and an interposer structure 260. In some aspects, the packaging portion 250 may correspond to the second packaging portion 130 in FIG. 1, and the interposer structure 260 may correspond to the interposer structure 150 in FIG. 1. In some aspects, certain details and components of the second IC package example 200B may be simplified or omitted in FIG. 2B.

In some aspects, the second IC package example 200B may be considered as a variation of the first IC package example 200A. Accordingly, components in FIG. 2B that are the same or similar to those in FIG. 2A are given the same reference numbers or labels, and detailed description thereof may be omitted.

As shown in FIG. 2B, the packaging portion 250 may include a base structure 252 where an IC component 220 may be disposed thereon. In this example, the base structure 252 may include a redistribution layer, which may be a metallization structure and may be implemented with layers of conductive structures that are finer and more complex than those in a package substrate. In some aspects, a redistribution layer may be formed by building up layers of conductive structures by laminating and patterning coated conductive layers one after another. Moreover, the interposer structure 260 may include a redistribution layer.

In some aspects, each one of the plurality of interposer connection structures 230′ may include at least the bond wire pillar portion shown in the enlarged view of FIG. 2A, which may include the corresponding bond ball portion 232 and the corresponding bond wire portion 234. In some aspects, an upper end of the corresponding bond wire portion of each interposer connection structure of the plurality of interposer connection structures 230′ may be connected to the interposer structure 260, as the conductive structures of the interposer structure 260 may be formed directly on the upper ends of the bond wire portions. In some aspects, the second IC package example 200B may be used in a redistribution layer PoP packaging process.

In some aspects, compared to the first IC package example 200A, the interposer structure 260 that includes a redistribution layer may be formed directly on the upper ends of the plurality of interposer connection structures 230′, and the solder portions 236 may be omitted. In some aspects, the interposer structure 260 that includes a redistribution layer may allow an even tighter pitch P than the solder bonding example (e.g., the first IC package example 200A having the interposer structure 240 that includes a package substrate and connected by the solder portions 236). Accordingly, the plurality of interposer connection structures 230′ may have a pitch P equal to or less than 150 μm or even equal to or less than 100 μm. In some aspects, a distance D between the upper surface of the base structure 252 and the lower surface of the interposer structure 260 may be greater than 200 μm.

FIG. 2C illustrates a portion of a third IC package example 200C, according to aspects of the disclosure. As shown in FIG. 2C, the third IC package example 200C may include a packaging portion 270 and an interposer structure 260. In some aspects, the packaging portion 270 may correspond to the second packaging portion 130 in FIG. 1, and the interposer structure 260 may correspond to the interposer structure 150 in FIG. 1. In some aspects, certain details and components of the third IC package example 200C may be simplified or omitted in FIG. 2C.

In some aspects, the third IC package example 200C may be considered as a variation of the first IC package example 200A and the second IC package example 200B. Accordingly, components in FIG. 2C that are the same or similar to those in FIG. 2A and FIG. 2B are given the same reference numbers or labels, and detailed description thereof may be omitted.

As shown in FIG. 2C, the packaging portion 270 may include a base structure 212 where an IC component 220 may be disposed thereon. In this example, the base structure 212 may be a package substrate with conductive structures formed therein. Compared to the first IC package example 200A, the interposer structure 260 of the third IC package example 200C may be a redistribution layer. In some aspects, an upper end of the corresponding bond wire portion of each interposer connection structure of the plurality of interposer connection structures 230′ may be connected to the interposer structure 260. In some aspects, the second IC package example 200B may be used in a MEP process with a redistribution layer top.

In some aspects, compared to the first IC package example 200A, the interposer structure 260 that includes a redistribution layer may be formed directly on the upper ends of the plurality of interposer connection structures 230′, and the solder portions 236 may be omitted. In some aspects, the interposer structure 260 that includes a redistribution layer may allow an even tighter pitch P as described with reference to FIG. 2B. Accordingly, the plurality of interposer connection structures 230′ may have a pitch P equal to or less than 150 μm or even equal to or less than 100 μm. In some aspects, a distance D between the upper surface of the base structure 212 and the lower surface of the interposer structure 260 may be greater than 200 μm.

FIG. 2D illustrates a portion of a fourth IC package example 200D, according to aspects of the disclosure. As shown in FIG. 2D, the fourth IC package example 200D may include a packaging portion 280 and an interposer structure 240. In some aspects, the packaging portion 280 may correspond to the second packaging portion 130 in FIG. 1, and the interposer structure 240 may correspond to the interposer structure 150 in FIG. 1. In some aspects, certain details and components of the fourth IC package example 200D may be simplified or omitted in FIG. 2D.

In some aspects, the fourth IC package example 200D may be considered as a variation of the first IC package example 200A. Accordingly, components in FIG. 2D that are the same or similar to those in FIG. 2A are given the same reference numbers or labels, and detailed description thereof may be omitted.

As shown in FIG. 2D, the packaging portion 280 may include a molding compound portion 218 that does not cover an upper surface of the IC component 220. The packaging portion 280 may further include a thermal interface material layer 282 between the upper surface of the IC component 220 and the interposer structure 240. In some aspects, based on the insertion of the thermal interface material layer 282, there may be a gap between the molding compound portion 218 and the lower surface of the interposer structure 240.

In some aspects, the thermal interface material layer 282 may include a material with a thermal conductivity of equal to or greater than 3 W/m-K. In some aspects, the thermal interface material layer 282 may include a material with a thermal conductivity ranging from 3 to 10 W/m-K. In some aspects, the fourth IC package example 200D may be used in a MEP packaging process and may further reduce the pitch P and improve the thermal dissipation of the IC component 220.

In some aspects, the plurality of interposer connection structures 230 may have a pitch P equal to or less than 150 μm. In some aspects, the plurality of interposer connection structures 230 may have the pitch P ranging from 100 to 150 μm. In some aspects, a distance D between the upper surface of the base structure 212 and the lower surface of the interposer structure 240 may be greater than 200 μm.

In some aspects, the base structure 212 or the base structure 252 in FIGS. 2A-2D may be depicted as non-limiting examples. In some aspects, the base structure for any of the IC package examples 200A-200D may include a package substrate, a redistribution layer, or a combination thereof. In some aspects, the interposer connection structures 230 or 230′ in FIGS. 2A-2D may reduce the horizontal size of the IC package or increase the count per unit area of the interposer connection structures. In some aspects, the interposer connection structures 230 or 230′ in FIGS. 2A-2D may be manufactured based on a wire bonding process, which may be less expensive than the cost of the processes based on copper core balls or copper plated pillars.

In some aspects, the interposer connection structures 230 or 230′ in FIGS. 2A-2D may be used to connect two substrates, two redistribution layers, or a substrate and a redistribution layer in a MEP process, a PoP packaging process, a MEP-Pop process, a redistribution layer PoP packaging proves, a side-by-side packaging process, a die-to-wafer fusion packaging process, a split-die packaging process, a multi-die packaging process, a multi-chip module (MCM) packaging process, a system-in-package (SiP) packaging process, or a packaging process based on a combination of the above.

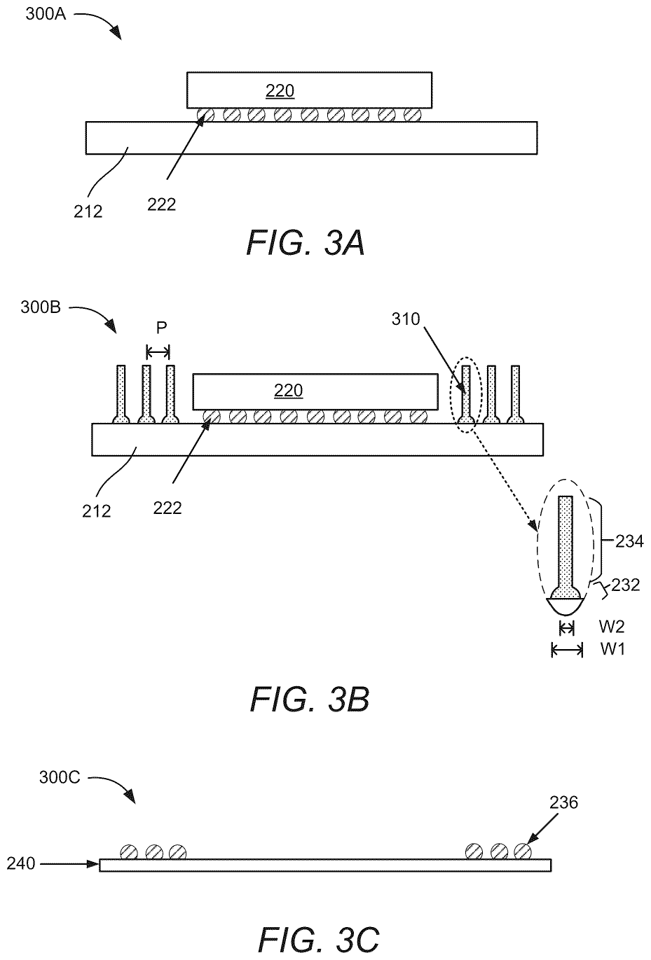

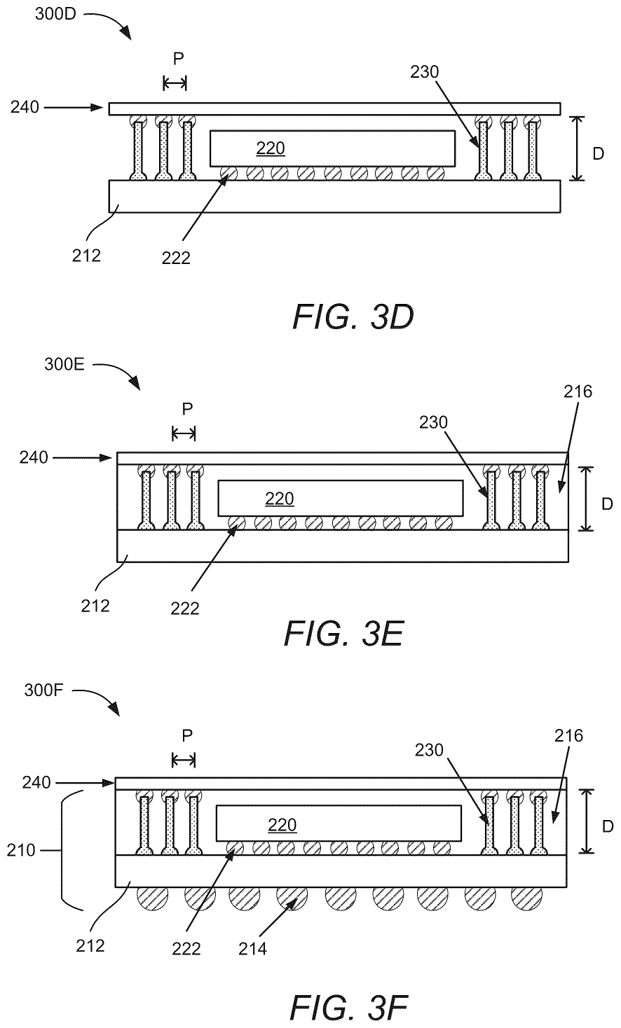

FIGS. 3A-3F illustrate structures at various stages of manufacturing an IC package, such as the first IC package example 200A in FIG. 2A, according to aspects of the disclosure. The components illustrated in FIGS. 3A-3F that are the same or similar to those of FIG. 2A are given the same reference numbers, and the detailed description thereof may be omitted.

As shown in FIG. 3A, a structure 300A may be formed based on disposing an IC component 220 on a base structure 212. In some aspects, the IC component 220 may be mounted on the base structure 212 through IC terminals 222 (e.g., solder bumps or copper pillar bumps). In some aspects, the IC component 220 may be an IC chip, or may be an assembly having a package substrate and the IC chip mounted on the package substrate. In some aspects, the base structure 212 as shown in FIG. 3A may be a package substrate. In some examples, the base structure 212 may be a redistribution layer. In some aspects, the base structure 212 at this stage may be in the form of being part of a wafer, a strip, or a panel on which one or more other base structures for one or more other IC packages are also provided. In some aspects, the base structure 212 may be a standalone base structure for forming one IC package.

As shown in FIG. 3B, a structure 300B may be formed based on forming a plurality of bond wire pillars 310 on an upper surface of the base structure 212. The plurality of bond wire pillars 310 will be the basis of forming a plurality of interpose connection structures 230 at a later stage. In some aspects, as shown in the enlarged view of an example bond wire pillar, each bond wire pillar may include a bond ball portion 232 that is connected to the base structure 212, and a bond wire portion 234 that is coupled to the bond ball portion 232 and extends upwardly. In some aspects, an lower end of each bond wire pillar may be connected to a corresponding conductive pad of the base structure 212. In some aspects, a width W1 of the bond ball portion 232 maybe greater than a width W2 of the bond wire portion 234. In some aspects, the plurality of bond wire pillars 310 may have a pitch P equal to or less than 150 μm or equal to or less than 100 μm. In some aspects, the pitch P may range from 100 to 150 μm. In some aspects, the plurality of bond wire pillars 310 may be formed based on a wire bonding process with a bond wire comprising a metal. In some aspects, the metal may include copper, aluminum, gold, or a combination thereof.

As shown in FIG. 3C, a structure 300C may be formed based on forming solder portions 236 on a lower surface of an interposer structure 240. In FIG. 3C, the interposer structure 240 is depicted in an up-side-down position with respect to the interposer structure 240 depicted in FIG. 2A. In some aspects, the solder portions 236 may be formed by paste printing a solder material on the lower surface of the interposer structure 240.

As shown in FIG. 3D, a structure 300D may be formed based on attaching the structure 300C to the structure 300B, where the solder portions 236 may bond the bond wire pillars 310 to the interposer structure 240. The combination of the solder portions 236 and the bond wire pillars 310 may become a plurality of interposer connection structures 230. Accordingly, the interposer structure 240 may be disposed over the IC component 220 and the plurality of interposer connection structures 230. Also, the plurality of interposer connection structures 230 may be configured to connect the base structure 212 and the interposer structure 240. In some aspects, a distance D between the upper surface of the base structure 212 and the lower surface of the interposer structure 240 may be greater than 200 μm.

As shown in FIG. 3E, a structure 300E may be formed based on the structure 300D by forming a molding compound portion 216 on the base structure 212 and surrounding at least the bond ball portions and a portion of the bond wire portions of the plurality of interposer connection structures 230. In some aspects, the molding compound portion 216 may be in contact with the upper surface of the base structure 212 and the lower surface of the interposer structure 240.

As shown in FIG. 3F, a structure 300F may be formed based on the structure 300E by forming a plurality of packaging terminals 214 (e.g., a plurality of solder bumps or copper pillar bumps) under the base structure 212, where the plurality of packaging terminals 214 are configured for connecting the resulting IC package (e.g., the first IC package example 200A) to an external component (e.g., a circuit board). Moreover, based on the base structure 212 in FIGS. 3A-3E being part of a wafer, a strip, or a panel, the structure 300F may be formed further based on performing a singulation process to separate the structure 300F from one or more other base structures for one or more other IC packages. In some aspects, the structure 300F may correspond to the first IC package example 200A.

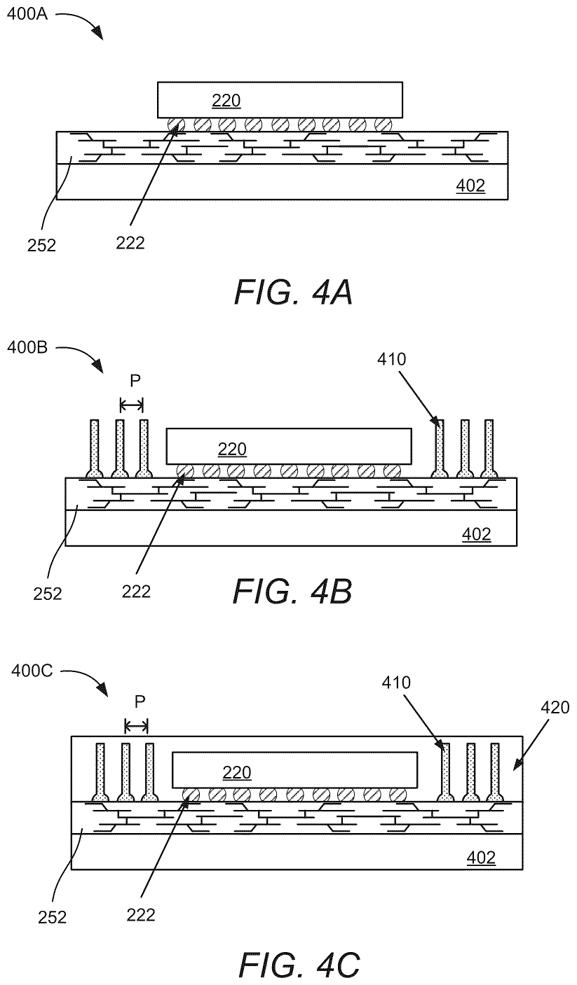

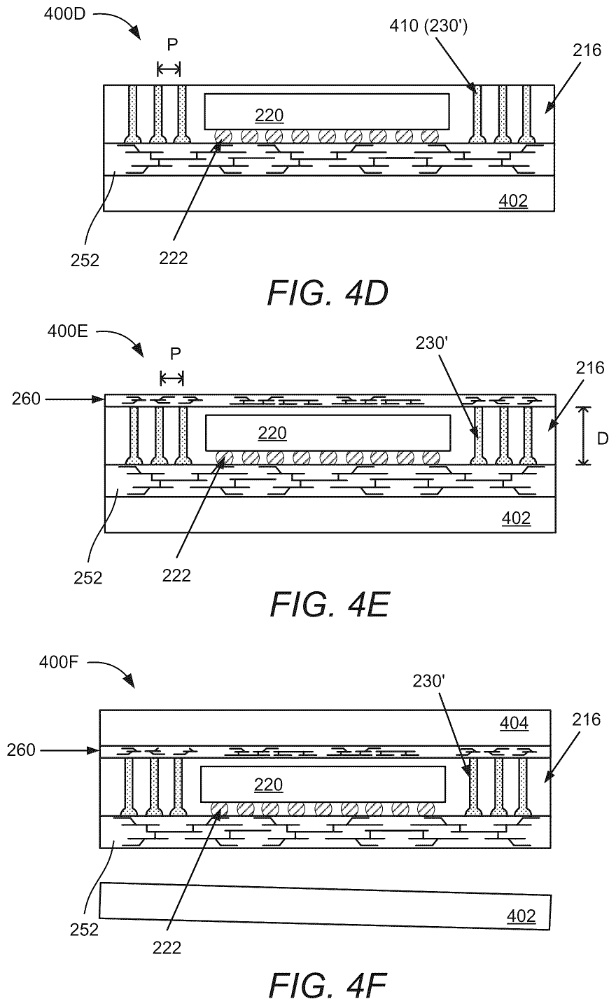

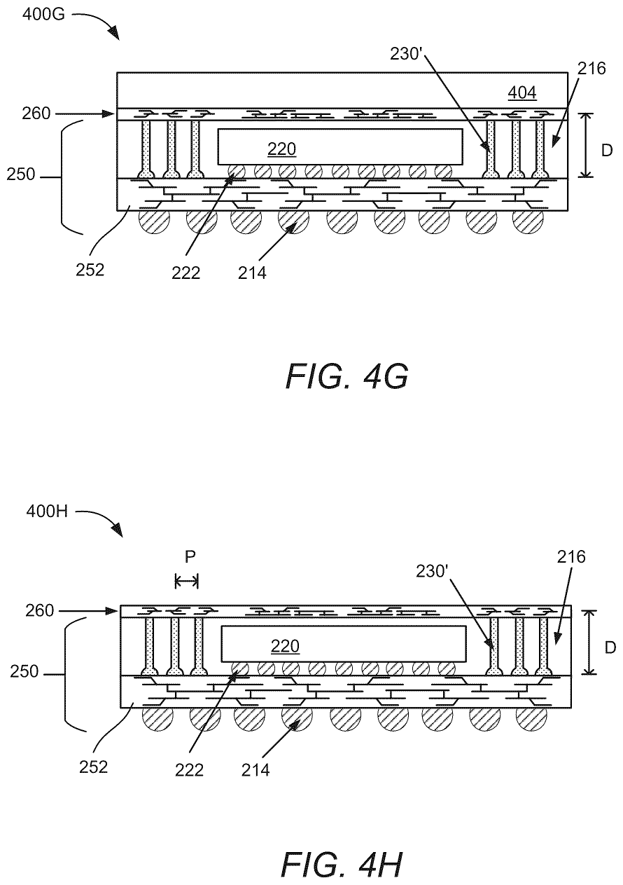

FIGS. 4A-4H illustrate structures at various stages of manufacturing an IC package, such as the second IC package example 200B in FIG. 2B, according to aspects of the disclosure. The components illustrated in FIGS. 4A-4H that are the same or similar to those of FIG. 2B are given the same reference numbers, and the detailed description thereof may be omitted.

As shown in FIG. 4A, a structure 400A may be formed based on disposing an IC component 220 on a base structure 252. In some aspects, the IC component 220 may be mounted on the base structure 212 through IC terminals 222 (e.g., solder bumps or copper pillar bumps). In some aspects, the IC component 220 may be an IC chip, or may be an assembly having a package substrate and the IC chip mounted on the package substrate. In some aspects, the base structure 252 as shown in FIG. 4A may be a redistribution layer formed on a carrier 402. In some examples, the base structure 252 may be a package substrate. In some aspects, the base structure 252 together with the carrier 402 at this stage may be in the form of being part of a wafer, a strip, or a panel on which one or more other base structures for one or more other IC packages are also provided. In some aspects, the base structure 252 may be a standalone base structure for forming one IC package.

As shown in FIG. 4B, a structure 400B may be formed based on forming a plurality of bond wire pillars 410 on an upper surface of the base structure 252. The plurality of bond wire pillars 410 will be the basis of forming a plurality of interpose connection structures 230′ at a later stage. In some aspects, each bond wire pillar of the plurality of bond wire pillars 410 may include a bond ball portion 232 that is connected to the base structure 252, and a bond wire portion 234 that is coupled to the bond ball portion 232 and extends upwardly, as similarly illustrated with reference to FIG. 3B. In some aspects, the plurality of bond wire pillars 410 may have a pitch P equal to or less than 150 μm. In some aspects, the pitch P may equal to or less than 100 μm, as the subsequently formed interposer structure 260 may be a redistribution layer. In some aspects, the plurality of bond wire pillars 410 may be formed based on a wire bonding process with a bond wire comprising a metal. In some aspects, the metal may include copper, aluminum, gold, or a combination thereof.

As shown in FIG. 4C, a structure 400C may be formed based on the structure 400B by forming a molding compound portion 420 on the base structure 252 and covering the IC component 220 and the bond wire pillars 410.

As shown in FIG. 4D, a structure 400D may be formed based on the structure 400C by polishing the molding compound portion 420 to expose upper ends of the bond wire portions of the bond wire pillars 410. In some aspects, the bond wire pillars 410 may become the plurality of interposer connection structures 230′ with exposed upper ends, and the polished molding compound portion 420 may become the molding compound portion 216.

As shown in FIG. 4E, a structure 400E may be formed based on the structure 400D by disposing an interposer structure 260 over the IC component 220 and the plurality of interposer connection structures 230′. In some aspects, the interposer structure 260 may be a redistribution layer that is formed on the molding compound portion 216 and the upper ends of the bond wire portions of the plurality of interposer connection structures 230′ after the polishing. In some aspects, a distance D between the upper surface of the base structure 252 and the lower surface of the interposer structure 260 may be greater than 200 μm.

As shown in FIG. 4F, a structure 400F may be formed based on the structure 400E by forming another carrier 404 on the interposer structure 260 and removing the carrier 402 under the base structure 252.

As shown in FIG. 4G, a structure 400G may be formed based on the structure 400F by forming a plurality of packaging terminals 214 (e.g., a plurality of solder bumps or copper pillar bumps) under the base structure 252, where the plurality of packaging terminals 214 are configured for connecting the resulting IC package (e.g., the second IC package example 200B) to an external component (e.g., a circuit board).

As shown in FIG. 4H, a structure 400H may be formed based on the structure 400G by removing the carrier 404. Moreover, based on the base structure 252 in FIGS. 4A-4G being part of a wafer, a strip, or a panel, the structure 400H may be formed further based on performing a singulation process to separate the structure 400H from one or more other base structures for one or more other IC packages. In some aspects, the structure 400H may correspond to the second IC package example 200B.

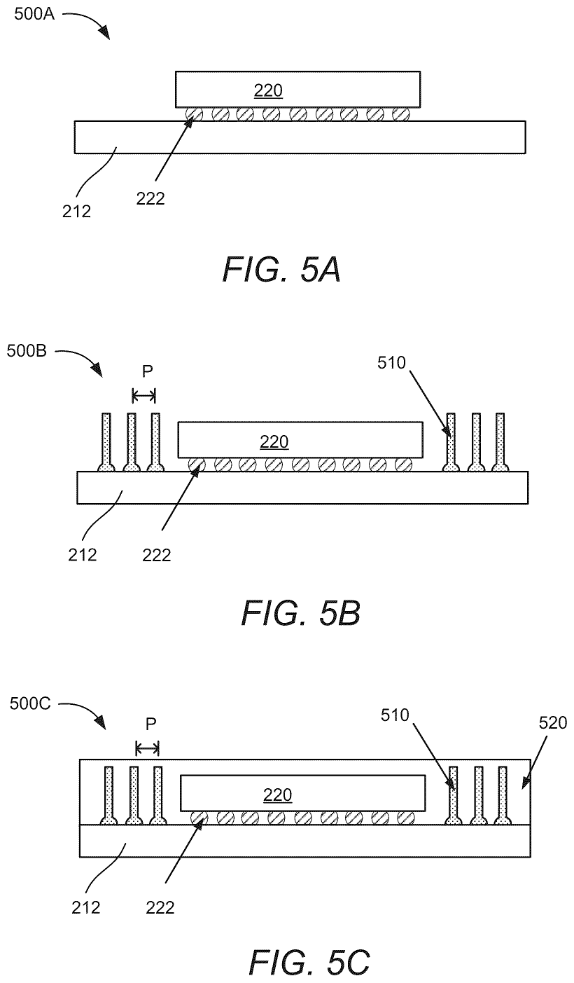

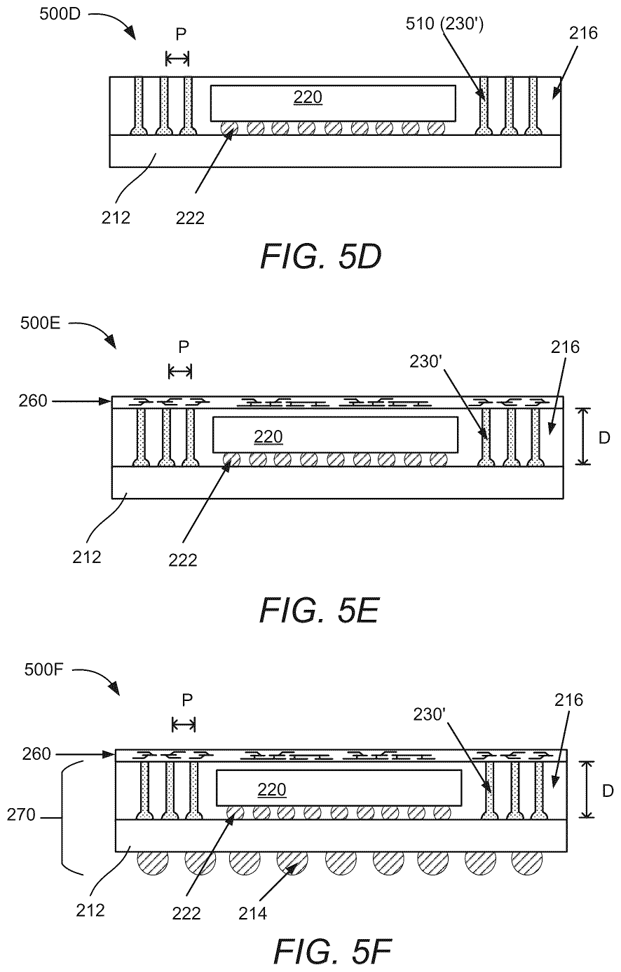

FIGS. 5A-5F illustrate structures at various stages of manufacturing an IC package, such as the third IC package example 200C in FIG. 2C, according to aspects of the disclosure. The components illustrated in FIGS. 5A-5F that are the same or similar to those of FIG. 2C are given the same reference numbers, and the detailed description thereof may be omitted.

As shown in FIG. 5A, a structure 500A may be formed based on disposing an IC component 220 on a base structure 212. In some aspects, the IC component 220 may be mounted on the base structure 212 through IC terminals 222 (e.g., solder bumps or copper pillar bumps). In some aspects, the IC component 220 may be an IC chip, or may be an assembly having a package substrate and the IC chip mounted on the package substrate. In some aspects, the base structure 212 as shown in FIG. 5A may be a package substrate. In some examples, the base structure 212 may be a redistribution layer. In some aspects, the base structure 212 at this stage may be in the form of being part of a wafer, a strip, or a panel on which one or more other base structures for one or more other IC packages are also provided. In some aspects, the base structure 212 may be a standalone base structure for forming one IC package.

As shown in FIG. 5B, a structure 500B may be formed based on forming a plurality of bond wire pillars 510 on an upper surface of the base structure 212. The plurality of bond wire pillars 510 will be the basis of forming a plurality of interpose connection structures 230′ at a later stage. In some aspects, each bond wire pillar of the plurality of bond wire pillars 510 may include a bond ball portion 232 that is connected to the base structure 212, and a bond wire portion 234 that is coupled to the bond ball portion 232 and extends upwardly, as similarly illustrated with reference to FIG. 3B. In some aspects, the plurality of bond wire pillars 510 may have a pitch P equal to or less than 150 μm. In some aspects, the pitch P may equal to or less than 100 μm, as the subsequently formed interposer structure 260 may be a redistribution layer. In some aspects, the plurality of bond wire pillars 510 may be formed based on a wire bonding process with a bond wire comprising a metal. In some aspects, the metal may include copper, aluminum, gold, or a combination thereof.

As shown in FIG. 5C, a structure 500C may be formed based on the structure 500B by forming a molding compound portion 520 on the base structure 212 and covering the IC component 220 and the bond wire pillars 510.

As shown in FIG. 5D, a structure 500D may be formed based on the structure 500C by polishing the molding compound portion 520 to expose upper ends of the bond wire portions of the bond wire pillars 510. In some aspects, the bond wire pillars 510 may become the plurality of interposer connection structures 230′ with exposed upper ends, and the polished molding compound portion 520 may become the molding compound portion 216.

As shown in FIG. 5E, a structure 500E may be formed based on the structure 500D by disposing an interposer structure 260 over the IC component 220 and the plurality of interposer connection structures 230′. In some aspects, the interposer structure 260 may be a redistribution layer that is formed on the molding compound portion 216 and the upper ends of the bond wire portions of the plurality of interposer connection structures 230′ after the polishing. In some aspects, a distance D between the upper surface of the base structure 212 and the lower surface of the interposer structure 260 may be greater than 200 μm.

As shown in FIG. 5F, a structure 500F may be formed based on the structure 500E by forming a plurality of packaging terminals 214 (e.g., a plurality of solder bumps or copper pillar bumps) under the base structure 212, where the plurality of packaging terminals 214 are configured for connecting the resulting IC package (e.g., the third IC package example 200C) to an external component (e.g., a circuit board). Moreover, based on the base structure 212 in FIGS. 5A-5E being part of a wafer, a strip, or a panel, the structure 500F may be formed further based on performing a singulation process to separate the structure 500F from one or more other base structures for one or more other IC packages. In some aspects, the structure 500F may correspond to the third IC package example 200C.

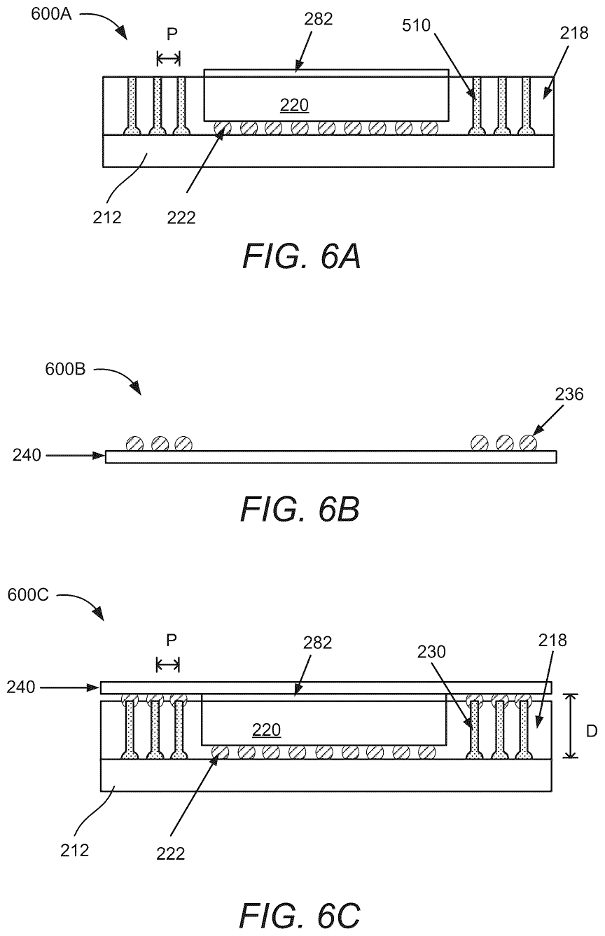

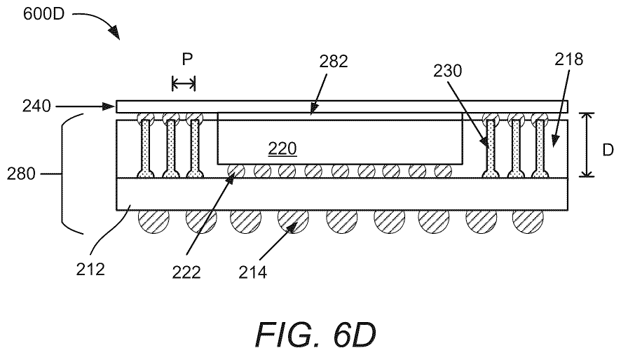

FIGS. 6A-6D, together with FIGS. 5A-5D, illustrate structures at various stages of manufacturing an IC package, such as the fourth IC package example 200D in FIG. 2D, according to aspects of the disclosure. The components illustrated in FIGS. 6A-6D that are the same or similar to those of FIG. 2C and FIGS. 5A-5D are given the same reference numbers, and the detailed description thereof may be omitted.

As shown in FIG. 6A, the polishing for forming the structure 500D may further expose an upper surface of the IC component 220. After the polishing, a thermal interface material layer 282 may be disposed on the upper surface of the IC component 220. In some aspects, the thermal interface material layer 282 may include a material with a thermal conductivity of equal to or greater than 3 W/m-K. In some aspects, the thermal interface material layer 282 may include a material with a thermal conductivity ranging from 3 to 10 W/m-K.

As shown in FIG. 6B, a structure 600B may be formed based on forming solder portions 236 on a lower surface of an interposer structure 240. In FIG. 6B, the interposer structure 240 is depicted in an up-side-down position with respect to the interposer structure 240 depicted in FIG. 2D. In some aspects, the solder portions 236 may be formed by paste printing a solder material on the lower surface of the interposer structure 240.

As shown in FIG. 6C, a structure 600C may be formed based on attaching the structure 600B to the structure 600A, where the solder portions 236 may bond the bond wire pillars 510 to the interposer structure 240. The combination of the solder portions 236 may bond the bond wire pillars 510 may become a plurality of interposer connection structures 230. Accordingly, the interposer structure 240 may be disposed over the IC component 220 and the plurality of interposer connection structures 230. Also, the plurality of interposer connection structures 230 may be configured to connect the base structure 212 and the interposer structure 240. In some aspects, a distance D between the upper surface of the base structure 212 and the lower surface of the interposer structure 240 may be greater than 200 μm. In some aspects, because of the thermal interface material layer 282, there may be a gap between the molding compound portion 218 and the lower surface of the interposer structure 240.

As shown in FIG. 6D, a structure 600D may be formed based on the structure 600C by forming a plurality of packaging terminals 214 (e.g., a plurality of solder bumps or copper pillar bumps) under the base structure 212, where the plurality of packaging terminals 214 are configured for connecting the resulting IC package (e.g., the fourth IC package example 200D) to an external component (e.g., a circuit board). Moreover, based on the base structure 212 in FIGS. 6A-6C being part of a wafer, a strip, or a panel, the structure 600D may be formed further based on performing a singulation process to separate the structure 600D from one or more other base structures for one or more other IC packages. In some aspects, the structure 600D may correspond to the fourth IC package example 200D.

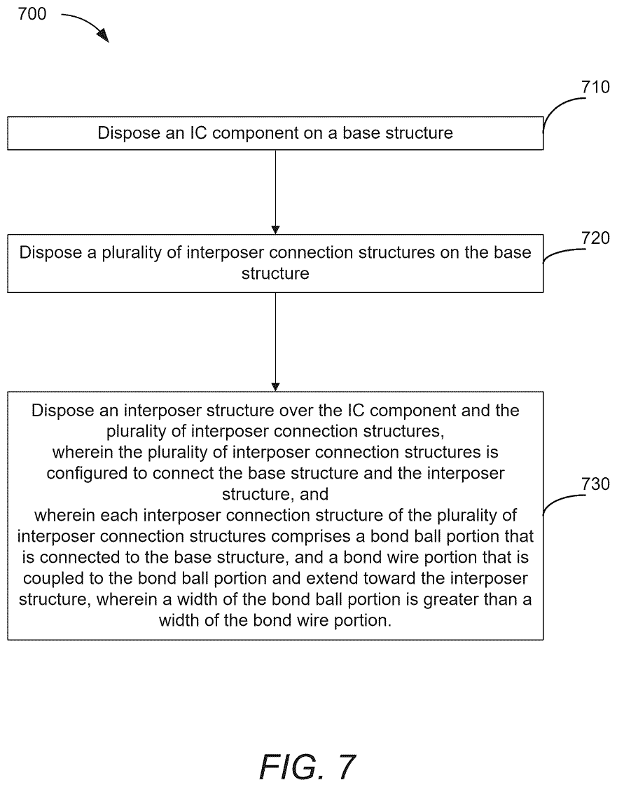

FIG. 7 illustrates a method 700 for manufacturing an IC package (such as the IC package example 200A, 200B, 200C, and/or 200D), according to aspects of the disclosure. In some aspects, FIGS. 3A-3F, FIGS. 4A-4H, FIGS. 5A-5F, and FIGS. 6A-6D may depict portions of the IC package examples at different stages of manufacturing according to the method 700.

At operation 710, an IC component (e.g., the IC component 220) may be disposed on a base structure (e.g., the base structure 212 or the base structure 252). In some aspects, the IC component 220 may be an IC chip, or an assembly having a package substrate and the IC chip mounted on the package substrate. In some aspects, the base structure may be a package substrate (e.g., the base structure 212) or a redistribution layer (e.g., the base structure 252). In some aspects, operation 710 may correspond to the stages as depicted in FIG. 3A, FIG. 4A, and FIG. 5A.

At operation 720, a plurality of interposer connection structures (e.g., the plurality of interposer connection structures 230 or the plurality of interposer connection structures 230′) may be disposed on the base structure. In some aspects, the disposing the plurality of interposer connection structures may include, for each interposer connection structure of the plurality of interposer connection structures, forming a corresponding bond ball portion and a corresponding bond wire portion based on a wire bonding process with a bond wire comprising a metal (e.g., disposing the bond wire pillars 310, 410, or 510 in FIG. 3B, FIG. 4B, and FIG. 5B). In some aspects, the metal comprises copper, aluminum, gold, or a combination thereof.

In some aspects, the plurality of interposer connection structures may have a pitch equal to or less than 150 μm. In some aspects, the plurality of interposer connection structures may have the pitch equal to or less than 100 μm.

At operation 730, an interposer structure (e.g., the interposer structure 240 or interposer structure 260) may be disposed over the IC component and the plurality of interposer connection structures. In some aspects, the plurality of interposer connection structures is configured to connect the base structure and the interposer structure. In some aspects, each interposer connection structure of the plurality of interposer connection structures may include a bond ball portion that is connected to the base structure, and a bond wire portion that is coupled to the bond ball portion and extends toward the interposer structure. In some aspects, for each interposer connection structure of the plurality of interposer connection structures, a width of the bond ball portion may be greater than a width of the bond wire portion.

In some aspects, a distance between an upper surface of the base structure and a lower surface of the interposer structure may be greater than 200 μm.

In some aspects, the method 700 may further include forming a molding compound portion on the base structure and surrounding at least the bond ball portions and a portion of the bond wire portions of the plurality of interposer connection structures. In some aspects, the method 700 may further include polishing the molding compound portion to expose upper ends of the bond wire portions of the plurality of interposer connection structures.

In some aspects, the polishing may expose the upper surface of the IC component, and the method 700 may further include disposing a thermal interface material layer on an upper surface of the IC component after the polishing.

In some aspects, the interposer structure may be a package substrate (e.g., the interposer structure 240 in FIGS. 2A and 2D). In some aspects, the disposing the interposer structure may include forming solder portions on a lower surface of the interposer structure, and bonding the interposer structure and upper ends of the bond wire portions of the plurality of interposer connection structures based on the solder portions.

In some aspects, the interposer structure may be a redistribution layer (e.g., the interposer structure 260 in FIGS. 2B and 2C). In some aspects, the method 700 may further include forming the redistribution layer on the molding compound portion and the upper ends of the bond wire portions of the plurality of interposer connection structures after the polishing.

In some aspects, after operation 730, the method 700 may further include forming a plurality of solder bumps or copper pillar bumps under the base structure. In some aspects, the plurality of solder bumps or copper pillar bumps may be configured for connecting the IC package to a circuit board.

A technical advantage of the method 700 corresponds to manufacturing an integrated circuit (IC) package that includes interposer connections structures formed based on a wire bonding process. In some aspects, the interposer connections structures formed based on a wire bonding process may reduce a horizontal size of the IC package and/or increase a count per unit area of the interposer connections structures. In some aspects, the interposer connections structures formed based on a wire bonding process may have a greater height versus pitch ratio than other solutions (e.g., copper core balls or plated copper pillars) to accommodate a thickener IC component between an interposer structure and a base structure of the IC package. Also, the manufacturing cost of the interposer connection structures based on the wire bonding process may be less expensive than other alternative implementations based on copper core balls or plated copper pillars.

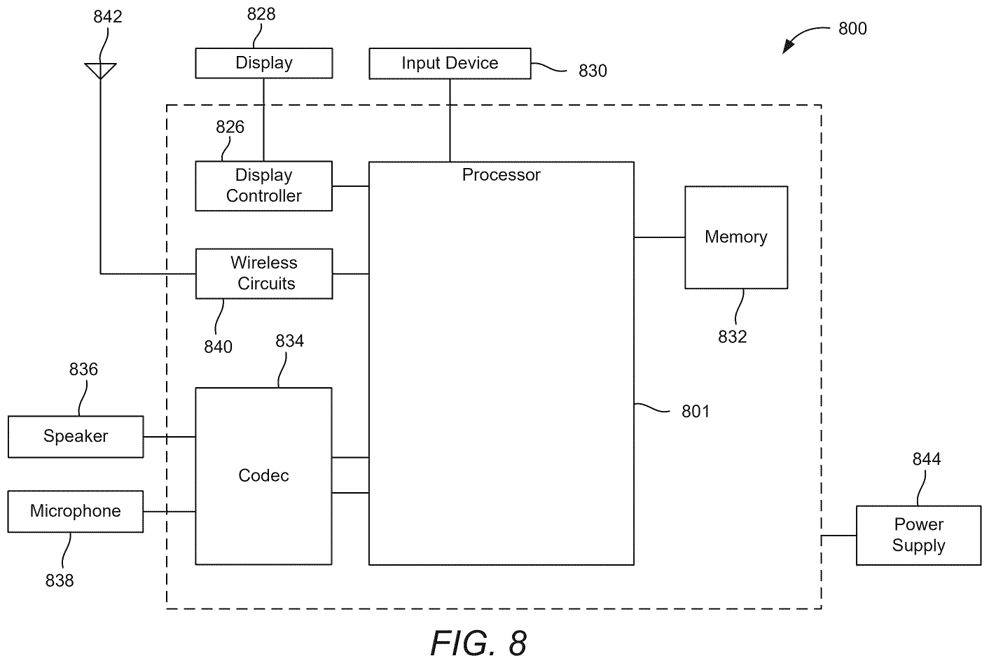

FIG. 8 illustrates a mobile device 800, according to aspects of the disclosure. In some aspects, the mobile device 800 may be implemented by including a IC device that is implemented based on the IC package disclosed herein.

In some aspects, mobile device 800 may be configured as a wireless communication device. As shown, mobile device 800 includes processor 801. Processor 801 may be communicatively coupled to memory 832 over a link, which may be a die-to-die or chip-to-chip link. Mobile device 800 also includes display 828 and display controller 826, with display controller 826 coupled to processor 801 and to display 828. The mobile device 800 may include input device 830 (e.g., physical, or virtual keyboard), power supply 844 (e.g., battery), speaker 836, microphone 838, and wireless antenna 842. In some aspects, the power supply 844 may directly or indirectly provide the supply voltage for operating some or all of the components of the mobile device 800.

In some aspects, FIG. 8 may include coder/decoder (CODEC) 834 (e.g., an audio and/or voice CODEC) coupled to processor 801; speaker 836 and microphone 838 coupled to CODEC 834; and wireless circuits 840 (which may include a modem, RF circuitry, filters, etc.) coupled to wireless antenna 842 and to processor 801.

In some aspects, one or more of processor 801 (e.g., SoCs, application processor (AP)), display controller 826, memory 832, CODEC 834, and wireless circuits 840 (e.g., baseband interface) including IC devices that are packaged as IC packages according to the various aspects described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

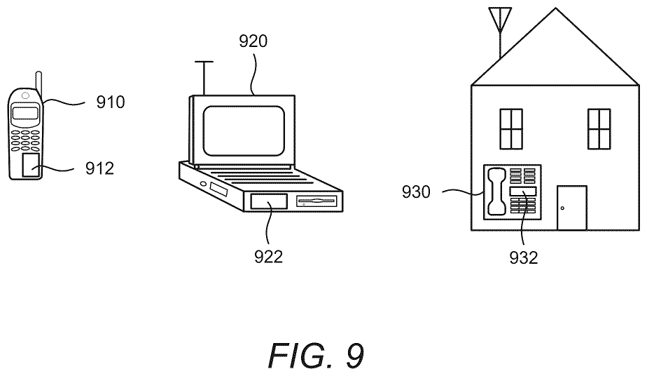

FIG. 9 illustrates various electronic devices 910, 920, and 930 that may incorporate IC devices 912, 922, and 932, which may be packaged as IC packages described herein, according to aspects of the disclosure.

For example, a mobile phone device 910, a laptop computer device 920, and a fixed location terminal device 930 may each be considered generally user equipment (UE) and may include one or more IC devices, such as IC devices 912, 922, and 932, and a power supply to provide the supply voltages to power the IC devices. The IC devices 912, 922, and 932 may be, for example, correspond to an IC device packaged as an IC package having a package substrate manufactured based on the examples described above with reference to FIGS. 2A-6D.

The devices 910, 920, and 930 illustrated in FIG. 9 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-9 may be rearranged and/or combined into a single component, process, feature, or function or incorporated in several components, processes, or functions. Additional elements, components, processes, and/or functions may also be added without departing from the disclosure. In some implementations, FIGS. 1-9 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An integrated circuit (IC) package, comprising: a base structure; an IC component disposed on the base structure; a plurality of interposer connection structures disposed on the base structure; and an interposer structure disposed over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

Clause 2. The IC package of clause 1, wherein: the bond ball portion and the bond wire portion of each one of the plurality of interposer connection structures comprise a metal.

Clause 3. The IC package of clause 2, wherein: the metal comprises copper, aluminum, gold, or a combination thereof.

Clause 4. The IC package of any of clauses 1 to 3, wherein: the plurality of interposer connection structures has a pitch equal to or less than 150 micrometers (μm).

Clause 5. The IC package of clause 4, wherein: the plurality of interposer connection structures has the pitch equal to or less than 100 μm.

Clause 6. The IC package of any of clauses 1 to 5, wherein: a distance between an upper surface of the base structure and a lower surface of the interposer structure is greater than 200 micrometers (μm).

Clause 7. The IC package of any of clauses 1 to 6, wherein: each interposer connection structure of the plurality of interposer connection structures further comprises a solder portion connecting an upper end of the corresponding bond wire portion and the interposer structure.

Clause 8. The IC package of any of clauses 1 to 7, further comprising: a molding compound portion between the base structure and the interposer structure and surrounding at least the bond ball portions and a portion of the bond wire portions of the plurality of interposer connection structures.

Clause 9. The IC package of clause 8, further comprising: a thermal interface material layer between an upper surface of the IC component and the interposer structure.

Clause 10. The IC package of any of clauses 1 to 6, wherein: the interposer structure comprises a redistribution layer, and an upper end of the corresponding bond wire portion of each interposer connection structure of the plurality of interposer connection structures is connected to the interposer structure.

Clause 11. The IC package of any of clauses 1 to 10, wherein: the base structure comprises a package substrate or a redistribution layer.

Clause 12. The IC package of any of clauses 1 to 11, further comprising: a plurality of solder bumps or copper pillar bumps under the base structure and configured for connecting the IC package to a circuit board.

Clause 13. The IC package of any of clauses 1 to 12, wherein: the IC component is an IC chip, or an assembly having a package substrate and the IC chip mounted on the package substrate.

Clause 14. A method of manufacturing an integrated circuit (IC) package, comprising: disposing an IC component on a base structure; disposing a plurality of interposer connection structures on the base structure; and disposing an interposer structure over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

Clause 15. The method of clause 14, wherein: the disposing the plurality of interposer connection structures comprises, for each interposer connection structure of the plurality of interposer connection structures, forming the corresponding bond ball portion and the corresponding bond wire portion based on a wire bonding process with a bond wire that comprises a metal.

Clause 16. The method of clause 15, wherein: the metal comprises copper, aluminum, gold, or a combination thereof.

Clause 17. The method of any of clauses 14 to 16, wherein: the plurality of interposer connection structures has a pitch equal to or less than 150 micrometers (μm).

Clause 18. The method of any of clauses 14 to 17, wherein: a distance between an upper surface of the base structure and a lower surface of the interposer structure is greater than 200 micrometers (μm).

Clause 19. The method of any of clauses 14 to 18, wherein: the disposing the interposer structure comprises: forming solder portions on a lower surface of the interposer structure; and bonding the interposer structure and upper ends of the bond wire portions of the plurality of interposer connection structures based on the solder portions.

Clause 20. The method of any of clauses 14 to 18, further comprising: forming a molding compound portion on the base structure and surrounding at least the bond ball portions and a portion of the bond wire portions of the plurality of interposer connection structures.

Clause 21. The method of clause 20, further comprising: polishing the molding compound portion to expose upper ends of the bond wire portions of the plurality of interposer connection structures.

Clause 22. The method of clause 21, further comprising: disposing a thermal interface material layer on an upper surface of the IC component after the polishing, wherein the polishing exposes the upper surface of the IC component.

Clause 23. The method of any of clauses 21 to 22, further comprising: forming a redistribution layer on the molding compound portion and the upper ends of the bond wire portions of the plurality of interposer connection structures after the polishing.

Clause 24. The method of any of clauses 14 to 23, further comprising: forming a plurality of solder bumps or copper pillar bumps under the base structure, the plurality of solder bumps or copper pillar bumps being configured for connecting the IC package to a circuit board.

Clause 25. An electronic device, comprising: an integrated circuit (IC) package that comprises: a base structure; an IC component disposed on the base structure; a plurality of interposer connection structures disposed on the base structure; and an interposer structure disposed over the IC component and the plurality of interposer connection structures, wherein the plurality of interposer connection structures is configured to connect the base structure and the interposer structure, and wherein each interposer connection structure of the plurality of interposer connection structures comprises: a bond ball portion that is connected to the base structure, and a bond wire portion that is coupled to the bond ball portion and extends toward the interposer structure, wherein a width of the bond ball portion is greater than a width of the bond wire portion.

Clause 26. The electronic device of clause 25, wherein: the bond ball portion and the bond wire portion of each one of the plurality of interposer connection structures comprise a metal, and the metal comprises copper, aluminum, gold, or a combination thereof.

Clause 27. The electronic device of any of clauses 25 to 26, wherein: the plurality of interposer connection structures has a pitch equal to or less than 150 micrometers (μm), and a distance between an upper surface of the base structure and a lower surface of the interposer structure is greater than 200 μm.

Clause 28. The electronic device of any of clauses 25 to 27, wherein: the interposer structure comprises a package substrate, and each interposer connection structure of the plurality of interposer connection structures further comprises a solder portion connecting an upper end of the corresponding bond wire portion and the interposer structure.

Clause 29. The electronic device of any of clauses 25 to 27, wherein: the interposer structure comprises a redistribution layer, and an upper end of the corresponding bond wire portion of each interposer connection structure of the plurality of interposer connection structures is connected to the interposer structure.

Clause 30. The electronic device of any of clauses 25 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An integrated circuit (IC) package, comprising:
a base structure;
an IC component disposed on the base structure;
a plurality of interposer connection structures disposed on the base structure; and
an interposer structure disposed over the IC component and the plurality of interposer connection structures,
wherein the plurality of interposer connection structures is configured to connect the base structure and the interposer structure, and
wherein each interposer connection structure of the plurality of interposer connection structures comprises:
a bond ball portion that is connected to the base structure, and
a bond wire portion that is coupled to the bond ball portion and extends toward the interposer structure,
wherein a width of the bond ball portion is greater than a width of the bond wire portion.

2. The IC package of claim 1, wherein:
the bond ball portion and the bond wire portion of each one of the plurality of interposer connection structures comprise a metal.

3. The IC package of claim 2, wherein:
the metal comprises copper, aluminum, gold, or a combination thereof.

4. The IC package of claim 1, wherein:
the plurality of interposer connection structures has a pitch equal to or less than 150 micrometers (μm).

5. The IC package of claim 4, wherein:
the plurality of interposer connection structures has the pitch equal to or less than 100 μm.

6. The IC package of claim 1, wherein:
a distance between an upper surface of the base structure and a lower surface of the interposer structure is greater than 200 micrometers (μm).

7. The IC package of claim 1, wherein:
each interposer connection structure of the plurality of interposer connection structures further comprises a solder portion connecting an upper end of the corresponding bond wire portion and the interposer structure.

8. The IC package of claim 1, further comprising:
a molding compound portion between the base structure and the interposer structure and surrounding at least the bond ball portions and a portion of the bond wire portions of the plurality of interposer connection structures.

9. The IC package of claim 8, further comprising:
a thermal interface material layer between an upper surface of the IC component and the interposer structure.

10. The IC package of claim 1, wherein:
the interposer structure comprises a redistribution layer, and
an upper end of the corresponding bond wire portion of each interposer connection structure of the plurality of interposer connection structures is connected to the interposer structure.

11. The IC package of claim 1, wherein:
the base structure comprises a package substrate or a redistribution layer.

12. The IC package of claim 1, further comprising:
a plurality of solder bumps or copper pillar bumps under the base structure and configured for connecting the IC package to a circuit board.

13. The IC package of claim 1, wherein:
the IC component is an IC chip, or an assembly having a package substrate and the IC chip mounted on the package substrate.

14. A method of manufacturing an integrated circuit (IC) package, comprising:
disposing an IC component on a base structure;
disposing a plurality of interposer connection structures on the base structure; and
disposing an interposer structure over the IC component and the plurality of interposer connection structures,
wherein the plurality of interposer connection structures is configured to connect the base structure and the interposer structure, and
wherein each interposer connection structure of the plurality of interposer connection structures comprises:
a bond ball portion that is connected to the base structure, and
a bond wire portion that is coupled to the bond ball portion and extends toward the interposer structure,
wherein a width of the bond ball portion is greater than a width of the bond wire portion.

15. The method of claim 14, wherein:
the disposing the plurality of interposer connection structures comprises, for each interposer connection structure of the plurality of interposer connection structures, forming the corresponding bond ball portion and the corresponding bond wire portion based on a wire bonding process with a bond wire that comprises a metal.

16. The method of claim 15, wherein:
the metal comprises copper, aluminum, gold, or a combination thereof.

17. The method of claim 14, wherein:
the plurality of interposer connection structures has a pitch equal to or less than 150 micrometers (μm).

18. The method of claim 14, wherein:
a distance between an upper surface of the base structure and a lower surface of the interposer structure is greater than 200 micrometers (μm).

19. The method of claim 14, wherein:
the disposing the interposer structure comprises:
forming solder portions on a lower surface of the interposer structure; and
bonding the interposer structure and upper ends of the bond wire portions of the plurality of interposer connection structures based on the solder portions.

20. The method of claim 14, further comprising:
forming a molding compound portion on the base structure and surrounding at least the bond ball portions and a portion of the bond wire portions of the plurality of interposer connection structures.

21. The method of claim 20, further comprising:
polishing the molding compound portion to expose upper ends of the bond wire portions of the plurality of interposer connection structures.

22. The method of claim 21, further comprising:
disposing a thermal interface material layer on an upper surface of the IC component after the polishing,
wherein the polishing exposes the upper surface of the IC component.

23. The method of claim 21, further comprising:
forming a redistribution layer on the molding compound portion and the upper ends of the bond wire portions of the plurality of interposer connection structures after the polishing.

24. The method of claim 14, further comprising:
forming a plurality of solder bumps or copper pillar bumps under the base structure, the plurality of solder bumps or copper pillar bumps being configured for connecting the IC package to a circuit board.

25. An electronic device, comprising:
an integrated circuit (IC) package that comprises:
a base structure;
an IC component disposed on the base structure;
a plurality of interposer connection structures disposed on the base structure; and
an interposer structure disposed over the IC component and the plurality of interposer connection structures,
wherein the plurality of interposer connection structures is configured to connect the base structure and the interposer structure, and
wherein each interposer connection structure of the plurality of interposer connection structures comprises:
a bond ball portion that is connected to the base structure, and
a bond wire portion that is coupled to the bond ball portion and extends toward the interposer structure,
wherein a width of the bond ball portion is greater than a width of the bond wire portion.

26. The electronic device of claim 25, wherein:
the bond ball portion and the bond wire portion of each one of the plurality of interposer connection structures comprise a metal, and
the metal comprises copper, aluminum, gold, or a combination thereof.

27. The electronic device of claim 25, wherein:
the plurality of interposer connection structures has a pitch equal to or less than 150 micrometers (μm), and
a distance between an upper surface of the base structure and a lower surface of the interposer structure is greater than 200 μm.

28. The electronic device of claim 25, wherein:
the interposer structure comprises a package substrate, and
each interposer connection structure of the plurality of interposer connection structures further comprises a solder portion connecting an upper end of the corresponding bond wire portion and the interposer structure.

29. The electronic device of claim 25, wherein:
the interposer structure comprises a redistribution layer, and
an upper end of the corresponding bond wire portion of each interposer connection structure of the plurality of interposer connection structures is connected to the interposer structure.

30. The electronic device of claim 25, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
